(19) United States
(12) Patent Application Publication
(10) Pub. No.: US 2026/0056479 A1
(43) Pub. Date: Feb. 26, 2026

(54) MASK STAGE INCLUDING A HEIGHT ADJUSTMENT BLOCK AND DEPOSITION DEVICE INCLUDING THE SAME

(71) Applicant: SAMSUNG DISPLAY CO., LTD., YONGIN-SI (KR)

(72) Inventors: DONGWOOK KIM, Yongin-si (KR); YEONG-MIN KIM, Yongin-si (KR); YOUNGSUN CHO, Yongin-si (KR); JAEMORK PARK, Yongin-si (KR); MINKOOK AHN, Yongin-si (KR); SANG MIN YI, Yongin-si (KR); SEONGCHEOL LEE, Yongin-si (KR); SANGJIN HAN, Yongin-si (KR)

(21) Appl. No.: 19/208,827

(22) Filed: May 15, 2025

(30) Foreign Application Priority Data
Aug. 21, 2024 (KR) 10-2024-0112170

(51) Int. Cl. G03F 7/00

(52) U.S. Cl. CPC G03F 7/70716; G03F 7/70758; G03F 7/70875

(57) ABSTRACT

A mask stage includes a frame including an opening portion and an outer portion surrounding the opening portion, the outer portion including a first to fourth outer portions, disposed in a plane defined by a first direction and a second direction crossing the first direction, a plurality of internal height adjustment blocks disposed at the first to fourth outer portions, a plurality of external height adjustment blocks disposed at the first to fourth outer portions and disposed spaced apart from the opening portion with the plurality of internal height adjustment blocks disposed therebetween, and a plurality of linear drivers connected to the plurality of internal height adjustment blocks and the plurality of external height adjustment blocks.

### CROSS-REFERENCE TO RELATED APPLICATION

This application claims priority under 35 U.S.C. § 119 to Korean Patent Application No. 10-2024-0112170, filed on Aug. 21, 2024, in the Korean Intellectual Property Office, the content of which is incorporated by reference herein in its entirety.

### BACKGROUND

### 1. Technical Field

The disclosure generally relates to a mask stage. More specifically, the disclosure relates to a mask stage and a deposition device including the mask stage with a height adjustment block.

### 2. Discussion of Related Art

Display devices connect users with information. Display devices are becoming increasingly used as information technology advances. Various types of display devices are widely used across different fields. These display devices include, for example, liquid crystal displays (“LCD”s), organic light-emitting displays (“OLED”s), and plasma displays (“PDP”s).

A display device may include a display panel for displaying an image, and the display panel may include a plurality of pixels. Each pixel may include a driver, such as a transistor, and a light-emitting device, such as an organic light-emitting diode. The light-emitting device may be formed by depositing electrodes and light-emitting patterns on a substrate.

The light-emitting patterns may be formed on the substrate using a mask with defined openings. Deposition technologies using large-area substrates and large-area masks may be used to improve yield.

### SUMMARY

An embodiment of the disclosure provides a mask stage that compensates pixel-per-accuracy (“PPA”) of the mask by controlling flatness.

An embodiment of the disclosure provides a deposition device with improved deposition accuracy by including the mask stage.

A mask stage according to an embodiment of the disclosure includes a frame including an opening portion and an outer portion surrounding the opening portion, the outer portion including a first outer portion, a second outer portion, a third outer portion, and a fourth outer portion, disposed in a plane defined by a first direction and a second direction crossing the first direction, a plurality of internal height adjustment blocks disposed at the first outer portion, the second outer portion, the third outer portion, and the fourth outer portion, a plurality of external height adjustment blocks disposed at the first outer portion, the second outer portion, the third outer portion, and the fourth outer portion and disposed spaced apart from the opening portion with the plurality of internal height adjustment blocks disposed therebetween, and a plurality of linear drivers connected to the plurality of internal height adjustment blocks and the plurality of external height adjustment blocks.

In an embodiment, the first outer portion and the third outer portion may be first sides parallel to each other in the first direction, the second outer portion and the fourth outer portion may be second sides parallel to each other in the second direction, two or more of the external height adjustment blocks may be disposed at each of the second sides and at each of the first sides, and two or more of the internal height adjustment blocks may be disposed at each of the second sides and at each of the first sides.

In an embodiment, each linear driver of the plurality of linear drivers may be connected to an internal height adjustment block of the plurality of internal height adjustment blocks and an external height adjustment block of the plurality of external height adjustment blocks.

In an embodiment, first linear drivers of the plurality of linear drivers may be disposed adjacent to a center portion of each of the first and third outer portions and second linear drivers of the plurality of linear drivers may be disposed adjacent to opposite end portions of each of the second and fourth outer portions.

In an embodiment, a plurality of passive height adjustment blocks may be disposed at each of the first to fourth outer portions, wherein the plurality of internal height adjustment blocks and the plurality of external height adjustment blocks may be active height adjustment blocks connected to the plurality of linear drivers.

In an embodiment, the mask stage may further include a temperature sensor disposed at the outer portion that detects a temperature of a mask disposed on the frame.

In an embodiment, the temperature sensor may be disposed adjacent to the internal height adjustment block and the external height adjustment block connected to a first linear driver of the plurality of linear drivers.

In an embodiment, a first sensor may be configured to detect a gap between a mask disposed on the frame and the frame.

In an embodiment, the first sensor may be positioned between the internal height adjustment block and the external height adjustment block connected to a first linear driver of the plurality of linear drivers.

In an embodiment, each height adjustment block of the plurality of internal height adjustment blocks and the plurality of external height adjustment blocks connected to a linear driver of the plurality of linear drivers may include: a first wedge including a first incline surface, a second wedge including a second incline surface contacting the first incline surface and disposing to face in a third direction crossing both the first direction and the second direction, and a moving axis connected to the second wedge and moveable, by the linear driver, in the first direction, wherein movement of the second wedge in the first direction moves the first wedge in the third direction.

In an embodiment, the mask stage may further include a height adjustor disposed below at least one height adjustment block of the plurality of internal height adjustment blocks or the plurality of external height adjustment blocks, and having a pre-set height.

A mask according to an embodiment of the disclosure includes a frame including an opening portion and an outer portion surrounding the opening portion, the outer portion including a first outer portion, a second outer portion, a third outer portion, and a fourth outer portion, disposed in a plane defined by a first direction and a second direction crossing the first direction, a plurality of internal height adjustment blocks disposed at the first outer portion, the second outer portion, the third outer portion, and the fourth outer portion, a plurality of external height adjustment blocks disposed at the first outer portion, the second outer portion, the third outer portion, and the fourth outer portion and disposed spaced apart from the opening portion with the plurality of internal height adjustment blocks disposed therebetween, and a plurality of linear drivers, wherein each linear driver of the plurality of linear drivers includes a first actuator connected to an internal height adjustment block of the plurality of internal height adjustment blocks and a second actuator connected to an external height adjustment block of the plurality of external height adjustment blocks.

In an embodiment, a sensor may be configured to sense a gap between a mask disposed on the frame and the frame, and may be positioned between the internal height adjustment block and the external height adjustment block of each linear driver of the plurality of linear drivers.

A deposition device according to an embodiment of the disclosure includes a deposition source disposed in a chamber, a mask disposed opposite to the deposition source; and a mask stage that supports the mask including: a frame including an opening portion and an outer portion surrounding the opening portion, the outer portion including a first outer portion, a second outer portion, a third outer portion, and a fourth outer portion, disposed in a plane defined by a first direction and a second direction crossing the first direction; a plurality of internal height adjustment blocks disposed at the first outer portion, the second outer portion, the third outer portion, and the fourth outer portion; a plurality of external height adjustment blocks disposed at the first outer portion, the second outer portion, the third outer portion, and the fourth outer portion and disposed spaced apart from the opening portion with the plurality of internal height adjustment blocks disposed therebetween; and a plurality of linear drivers connected to the plurality of internal height adjustment blocks and the plurality of external height adjustment blocks.

In an embodiment, the linear driver may be operable in a vacuum state within the chamber.

In an embodiment, the first outer portion and the third outer portion may be first sides parallel to each other in the first direction, the second outer portion and the fourth outer portion may be second sides parallel to each other in the second direction, two or more of the plurality of external height adjustment blocks may be disposed at each of the second sides and at each of the first sides, and two or more of the plurality of internal height adjustment blocks may be disposed at each of the second sides and at each of the first sides.

In an embodiment, a plurality of passive height adjustment blocks may be disposed at each of the first to fourth outer portions, wherein the plurality of internal height adjustment blocks and the plurality of external height adjustment blocks are active height adjustment blocks connected to the plurality of linear drivers.

In an embodiment, the deposition device may further include: a temperature sensor disposed at the outer portion that detects a temperature of the mask disposed on the frame.

In an embodiment, the deposition device may further include: a first sensor that may be disposed on the frame and configured to detect a gap between the mask and the frame.

In an embodiment, each height adjustment block of the plurality of internal height adjustment blocks and the plurality of external height adjustment blocks connected to a linear driver of the plurality of linear drivers may include: a first wedge including a first incline surface, a second wedge including a second incline surface contacting the first incline surface and disposed in a third direction crossing both the first direction and the second direction, and a moving axis connected to the second wedge and moveable, by the linear driver, in the first direction, wherein a movement of the second wedge in the first direction moves the first wedge in the third direction.

A mask stage according to an embodiment of the disclosure disposed in a plane defined by a first direction and a second direction crossing the first direction may include a frame including an opening portion and an outer portion surrounding the opening portion, the outer portion including a first outer portion, a second outer portion, a third outer portion, and a fourth outer portion, a plurality of internal height adjustment blocks disposed adjacent to the opening portion at each outer portion, a plurality of external height adjustment blocks disposed spaced farther apart from the opening portion than the internal height adjustment blocks at each outer portion, and a plurality of linear drivers connected to the plurality of internal height adjustment blocks and the plurality of external height adjustment blocks. Accordingly, the mask's PPA may be automatically compensated while the equipment operates (e.g., under vacuum of a process chamber).

### BRIEF DESCRIPTION OF THE DRAWINGS

The accompanying drawings, which are included to provide a further understanding of the present invention, illustrate embodiments of the disclosure together with the description thereof, in which:

FIG. 1 is a view illustrating a deposition device according to an embodiment of the disclosure.

FIG. 2 is a plan view illustrating the mask stage included in the deposition device of FIG. 1.

FIG. 3 is view illustrating an area A of FIG. 2.

FIG. 4 is a cross-sectional view taken along a line I-I′ of FIG. 2.

FIG. 5 is a view illustrating the height adjustment block included in the mask stage of FIG. 2.

FIG. 6 is a view illustrating the height adjustor included in the mask stage of FIG. 2.

FIG. 7 and FIG. 8 are views illustrating a second sensor included in the mask stage of FIG. 2.

FIG. 9, FIG. 10, FIG. 11, and FIG. 12 are views illustrating a height adjustment block included in the mask stage of FIG. 2.

FIG. 13 is a view illustrating a pixel formed by the deposition process using the deposition device of FIG. 1.

### DETAILED DESCRIPTION

Embodiments of the disclosure will be more clearly understood from the following detailed description in conjunction with the accompanying drawings. Like reference numerals or symbols refer to like elements throughout, and overlapping descriptions of the same components may be omitted.

According to an embodiment of the disclosure, a mask stage may support a mask and include height adjustment blocks and a linear driver connected thereto. The height adjustment blocks or the mask stage may be adjusted to flatten a surface of the mask stage, which may compensate for a deformation in the mask, which may affect a pixel-per-accuracy (“PPA”) of the mask and mask frame.

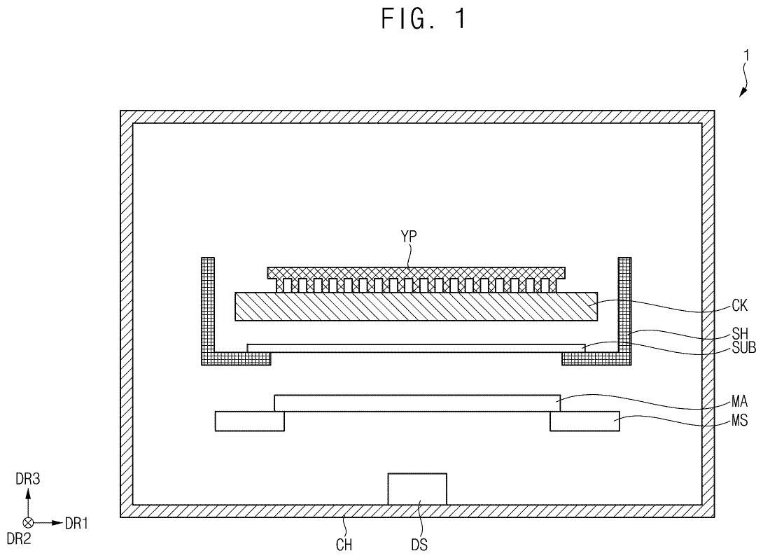

FIG. 1 is a view illustrating a deposition device according to an embodiment of the disclosure.

Referring to FIG. 1, a deposition device 1 according to an embodiment of the disclosure may include a chamber CH, a deposition source DS, a mask MA, a mask stage MS, a substrate holder SH, an electrostatic chuck CK, and a yoke plate YP. A substrate SUB may be disposed on the substrate holder SH.

In an embodiment, the chamber CH may define an internal space. In an embodiment, the deposition source DS may be disposed in the chamber CH. The deposition source DS may provide deposition material to the substrate SUB.

In an embodiment, the mask MA may be disposed opposite to the deposition source DS. The mask MA may be disposed opposite to, and above, the deposition source DS.

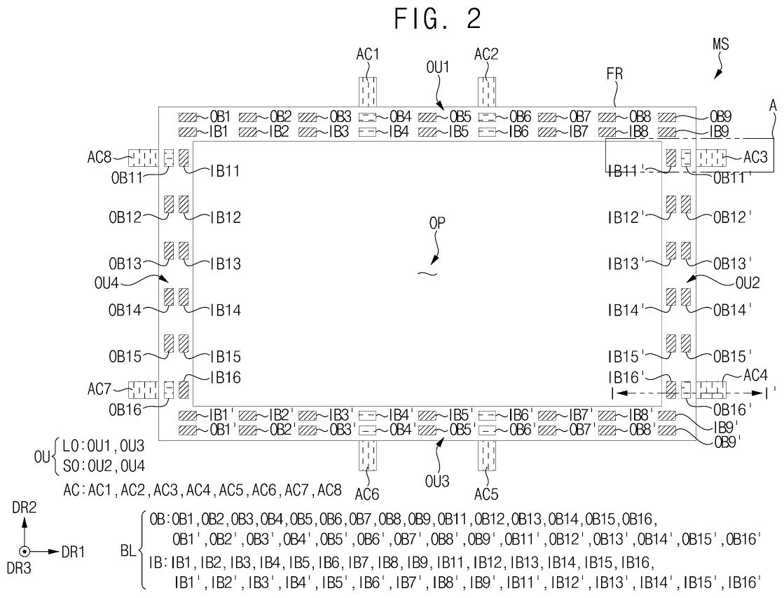

In an embodiment, the mask stage MS may support the mask MA. Detailed descriptions of the mask stage MS according to some embodiments are described herein with reference to FIG. 2.

The yoke plate YP may move the substrate SUB. The yoke plate YP may bring the mask MA and the substrate SUB into close contact.

The electrostatic chuck CK may chuck/de-chuck the substrate SUB.

The substrate holder SH may secure or release the substrate SUB. For example, the substrate holder SH may secure the substrate SUB and may release the substrate SUB when the substrate SUB is chucked by the electrostatic chuck CK.

For example, while a deposition process is in progress, the substrate holder SH may retreat to a position that does not overlap the mask MA. Accordingly, an occurrence of a shadow area in which the deposition material is not deposited in a portion obscured by the substrate holder SH may be prevented. According to an embodiment, the deposition process may be performed while the substrate SUB is chucked by the electrostatic chuck CK.

FIG. 1 is illustrative, and the disclosure is not limited thereto. For example, the deposition device 1 may include other components, or some of the components may be omitted or changed.

According to an embodiment, the deposition device 1 may be a horizontal deposition device. In the horizontal deposition device, each of the mask MA and the substrate SUB may be disposed parallel to a plane defined by a first direction DR1 and a second direction DR2, and the deposition material may be provided from the deposition source DS in a third direction DR3. Here, the second direction DR2 may intersect the first direction DR1, and the third direction DR3 may cross both the first direction DR1 and the second direction DR2. For example, the first direction DR1, the second direction DR2, and the third direction DR3 may be perpendicular to each other. However, the disclosure is not limited thereto.

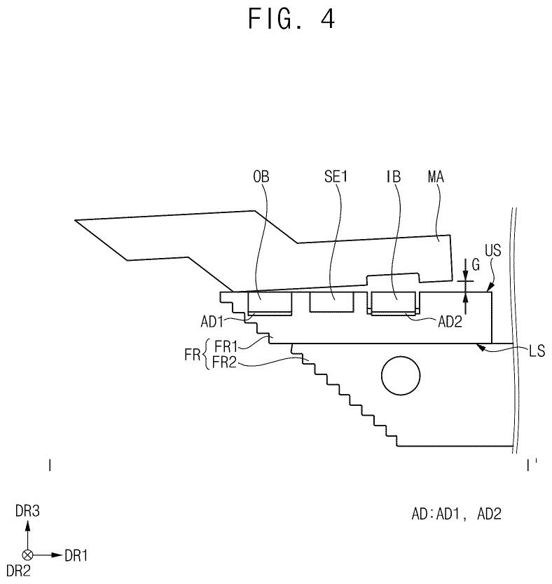

The deposition device 1 may include a controller. For example, the deposition device 1 may further include a first controller and a second controller. The second controller may be connected to a linear driver (e.g., a linear driver AC of FIG. 2) described herein. The second controller may control an operation of the linear driver. One or more second controllers may be provided. For example, a plurality of second controllers may be connected to the plurality of mask stages MS. The first controller may provide displacement data of the mask stage MS. For example, the first controller may provide the displacement data in a control signal that may be used to control a gap (e.g., a gap G of FIG. 4) between the mask MA and height adjustment blocks BL. The first controller may simultaneously provide the control signal to the plurality of second controllers. Accordingly, a flatness distribution between the deposition devices 1 may be controlled. For example, a flatness distribution between the deposition devices 1 may be reduced.

FIG. 2 is a plan view illustrating the mask stage MS included in the deposition device of FIG. 1.

Referring to FIG. 1 and FIG. 2, the mask stage MS according to an embodiment of the disclosure may include a frame FR, a plurality of height adjustment blocks BL, and the linear driver AC.

In an embodiment and when viewed in the plane defined by the first direction and the second direction crossing the first direction, the frame FR may include an opening portion OP and an outer portion OU. The outer portion OU may surround the opening portion OP, and include a first outer portion OU1, a second outer portion OU2, a third outer portion OU3, and a 4th outer portion OU4. The outer portion OU may have a shape of a rectangle. However, the disclosure is not limited thereto. For example, the outer portion OU have a shape of a polygon or a circle.

In an embodiment, the first outer portion OU1 and the third outer portion OU3 may be first sides LO disposed parallel to each other in the first direction DR1, and the second outer portion OU2 and the 4th outer portion OU 4 may be second sides SO disposed parallel to each other in the second direction DR2. The first sides LO may be relatively long sides and the second sides SO may be relatively short sides. In other words, a length in the second direction DR2 of the second outer portion OU2 and a length in the second direction DR2 of the 4th outer portion OU4 may be smaller than a length in the first direction DR1 of the first outer portion OU1 and a length in the first direction DR1 of the third outer portion OU3. However, the disclosure is not limited thereto. For example, the first sides LO and the second sides SO may have a same length. For example, the outer portion OU may have a shape of a square.

In an embodiment, the plurality of height adjustment blocks BL may include a plurality of external height adjustment blocks OB and a plurality of internal height adjustment blocks IB. For example, the plurality of internal height adjustment blocks IB may be disposed relatively close to the opening portion OP as compared to the plurality of external height adjustment blocks OB. A height, or heights, of surfaces of the plurality of external height adjustment blocks OB and the plurality of internal height adjustment blocks IB may be controlled. The mask MA may be disposed on the surfaces of the plurality of external height adjustment blocks OB and the plurality of internal height adjustment blocks IB.

The mask stage MS including the plurality of external height adjustment blocks OB and the plurality of internal height adjustment blocks IB may adjust a height of a mask MA in the third direction DR3. In addition, the plurality of external height adjustment blocks OB and the plurality of internal height adjustment blocks IB may be individually controlled. For example, the mask stage MS may control pitch and/or roll of the mask MA by independently moving one or more of the pluralities of external height adjustment blocks OB or internal height adjustment blocks IB. For example, the plurality of height adjustment blocks BL may adjust a flatness of the mask stage ST to an accuracy of about 50 micrometers. However, the disclosure is not limited thereto.

The plurality of height adjustment blocks BL may be attached to the frame FR. For example, a groove may be formed on an upper surface of the frame FR, and the plurality of height adjustment blocks BL may be attached into the groove. For example, the plurality of height adjustment blocks BL may be bolted into the groove. However, the disclosure is not limited thereto.

In an embodiment, the plurality of height adjustment blocks BL may be formed of material having high stiffness, low thermal expansion, and good vibration damping, which may improve precision and stability. In an embodiment, the plurality of height adjustment blocks BL may be formed of a metal, a metal allow, or a ceramic. However, the disclosure is not limited thereto.

In an embodiment, the plurality of internal height adjustment blocks IB may be disposed adjacent to the opening portion OP at each outer portion OU. In an embodiment, the plurality of internal height adjustment blocks IB may be disposed adjacent to the opening portion OP at each outer portion OU and between the plurality of external height adjustment blocks OB and the opening portion OP.

In an embodiment and as illustrated in FIG. 2, the plurality of the internal height adjustment blocks IB may include six internal height adjustment blocks disposed at each of the second sides SO and nine internal height adjustment blocks disposed at each of the first sides LO. However, the disclosure is not limited thereto, and a different number of internal height adjustment blocks may be disposed at each side of the outer portion OU.

In an embodiment, the plurality of external height adjustment blocks OB may be disposed spaced apart from the opening portion OP. In an embodiment, the plurality of external height adjustment blocks OB may be disposed spaced apart from the opening portion OP with the internal height adjustment blocks IB at each outer portion OU disposed between the plurality of external height adjustment blocks OB and the opening portion OP.

In an embodiment and as illustrated in FIG. 2, the plurality of the external height adjustment blocks OB may include six external height adjustment blocks disposed at each of the second sides SO and nine external height adjustment blocks disposed at each of the first sides LO. However, the disclosure is not limited thereto, and a different number of external height adjustment blocks may be disposed at each side of the outer portion OU.

As described herein the plurality of internal height adjustment blocks IB include first internal height adjustment blocks IB1, IB1′ disposed facing each other on opposite first sides LO. For example, the first internal height adjustment blocks IB1, IB1′ may be disposed on the first outer portion OU1 and the third outer portion OU3, respectively. Hereinafter, first internal height adjustment blocks IB1, IB1′ will be referred to as a first internal height adjustment block IB1, IB1′, unless the blocks are otherwise explicitly described individually. Similar usage is applied to the other height adjustment blocks of the plurality of height adjustment blocks BL. In an embodiment, a first internal height adjustment block IB1, IB1′, a second internal height adjustment block IB2, IB2′, a third internal height adjustment block IB3, IB3′, a 4th internal height adjustment block IB4, IB4′, a 5th internal height adjustment block IB5, IB5′, a 6th internal height adjustment block IB6, IB6′, a 7th internal height adjustment block IB7, IB7′, an 8th internal height adjustment block IB8, IB8′, and a 9th internal height adjustment block IB9, IB9′ may be disposed on each of the first sides LO in parallel with the first direction DR1.

In addition, a first external height adjustment block OB1, OB1′, a second external height adjustment block OB2, OB2′, a third external height adjustment block OB3, OB3′, a 4th external height adjustment block OB4, OB4′, a 5th external height adjustment block OB5, OB5′, a 6th external height adjustment block OB6, OB6′, a 7th external height adjustment block OB7, OB7′, an 8th external height adjustment block OB8, OB8′, and a 9th external height adjustment block OB9, OB9′ may be disposed on each of the first sides LO in parallel with the first direction DR1.

In an embodiment, an 11th internal height adjustment block IB11, IB11′, a 12th internal height adjustment block IB12, IB12′, a 13th internal height adjustment block IB13, IB13′, a 14th internal height adjustment block IB14, IB14′, a 15th internal height adjustment block IB15, IB15′, and a 16th internal height adjustment block IB16, IB16′ may be disposed on each of the second sides SO in parallel with a direction opposite to the second direction DR2.

In addition, a 11th external height adjustment block OB11, OB11′, a 12th external height adjustment block OB12, OB12′, a 13th external height adjustment block OB13, OB13′, a 14th external height adjustment block OB14, OB14′, a 15th external height adjustment block OB15, OB15′, and a 16th external height adjustment block OB16, OB16′ may be disposed on each of the second sides SO in parallel with the direction opposite to the second direction DR2.

However, the disclosure is not limited thereto. For example, the number of the plurality of internal height adjustment blocks IB and the plurality of external height adjustment blocks OB may be changed. Further, the plurality of internal height adjustment blocks IB and the plurality of external height adjustment blocks OB may be evenly distributed along the frame FR. For example, a distance between different adjacent blocks of the plurality of internal height adjustment blocks IB and the plurality of external height adjustment blocks OB may be the same. However, the disclosure is not limited thereto, and a distance between the blocks may be varied.

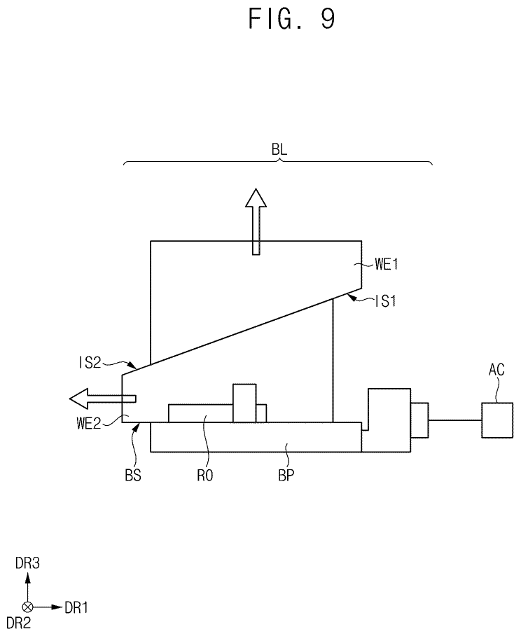

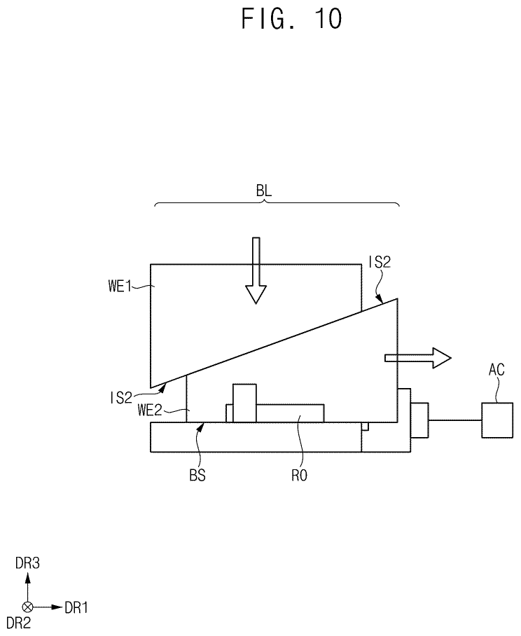

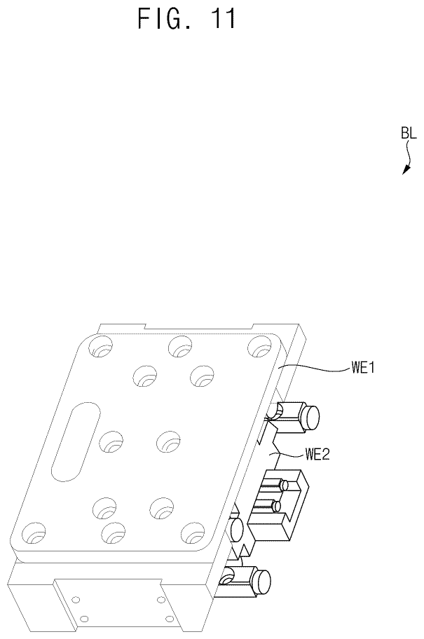

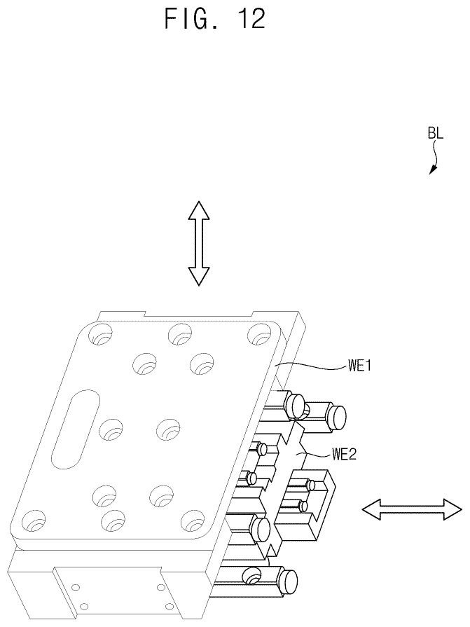

Detailed descriptions of a structure of the plurality of internal height adjustment blocks IB and the plurality of external height adjustment blocks OB according to some embodiments are described herein with reference to FIG. 9 and FIG. 10.

In an embodiment, the linear driver AC may be connected to one or more adjustments blocks among the plurality of external height adjustment blocks OB and the plurality of internal height adjustment blocks IB.

Hereinafter, for convenience of explanation, an active block may mean the plurality of external height adjustment blocks OB and the plurality of internal height adjustment blocks IB connected to the linear driver AC. As illustrated in FIG. 2, the active blocks are illustrated using an alternating horizontal line pattern, for example, the 4th external height adjustment block OB4, OB4′ and the 4th internal height adjustment block IB4, IB4′. In addition, a passive block may mean the plurality of external height adjustment blocks OB and the plurality of internal height adjustment blocks IB that are not connected to the linear driver AC. As illustrated in FIG. 2, the passive blocks are illustrated using a wide downward diagonal striped pattern, for example, the third external height adjustment block OB3, OB3′ and the third internal height adjustment block IB3, IB3′.

For example, the linear driver AC may be a linear actuator. The linear actuator may have high precision and may apply a large force. For example, the linear actuator may include a two-phase step motor having high-performance and low-vibration. For example, the linear driver AC may be a stepper motor linear actuator. For example, the linear driver AC may include a lead screw as a rotor, which may translate motor torque into linear thrust.

In an embodiment, the linear driver AC may be operatable in the vacuum state. For example, the linear actuator may operate in the vacuum of a process chamber for semiconductor wafer processing.

In an embodiment, the linear driver AC may be disposed adjacent to a center portion of each of the first and third outer portions OU1, OU3 (i.e., first sides LO), and adjacent to opposite end portions of each of the second and 4th outer portions OU2, OU4 (i.e., second sides SO). For example, in an embodiment, the linear driver AC may be connected to the 4th internal height adjustment block IB4, IB4′, the 4th external height adjustment block OB4, OB4′, the 6th internal height adjustment block IB6, IB′, the 6th external height adjustment block OB6, OB6′, the 11th external height adjustment block OB11, OB11′, and the 16th external height adjustment block OB16, OB16′.

For example, the linear driver AC may include a first linear driver AC1, a second linear driver AC2, a third linear driver AC3, a 4th linear driver AC4, and a 5th linear driver AC5, a 6th linear driver AC6, a 7th linear driver AC7, and an 8th linear driver AC8.

The first linear driver AC1 may be connected to the 4th internal height adjustment block IB4 and the 4th external height adjustment block OB4. The second linear driver AC2 may be connected to the 6th internal height adjustment block IB6 and the 6th external height adjustment block OB6. The third linear driver AC3 may be connected to the 11th external height adjustment block OB11′. The 4th linear driver AC4 may be connected to the 16th external height adjustment block OB16′. The 5th linear driver AC5 may be connected to the 6th internal height adjustment block IB6′ and the 6th external height adjustment block OB6′. The 6th linear driver AC6 may be connected to the 4th internal height adjustment block IB4′ and the 4th external height adjustment block OB4′. The 7th linear driver AC7 may be connected to the 16th external height adjustment block OB16. The 8th linear driver AC8 may be connected to the 11th external height adjustment block OB11.

In a case of a mask stage according to a comparative embodiment, a height adjustor having a pre-set height may be disposed to adjust the flatness of the stage. In this case, because the height of the height adjustor is fixed, the flatness of the mask stage according to the comparative embodiment is not adjustable while an equipment is in operation.

The mask stage MS according to an embodiment of the disclosure may include the active block connected the linear driver AC. In an embodiment, the linear driver AC may operate in the vacuum sate. For example, the linear driver AC may operate in the vacuum of a process chamber for semiconductor wafer processing. Accordingly, the flatness of the mask stage MS may be adjusted while the equipment is in operation.

TABLE 1

| | 8 | 12-A | 12-B | 12-C | 16 |
|---|---|---|---|---|---|
| distortion | X | X | ◯ | ◯ | ◯ |
| rotation | ◯ | ◯ | ◯ | ◯ | ◯ |
| U-shape | ◯ | ◯ | ◯ | ◯ | ◯ |
| XY reduction | ◯ | ◯ | ◯ | ◯ | ◯ |
| Y reduction | X | ◯ | X | ◯ | ◯ |
| Y expansion | X | X | X | X | ◯ |
| X reduction | X | X | ◯ | ◯ | ◯ |
| X expansion | X | X | X | X | X |

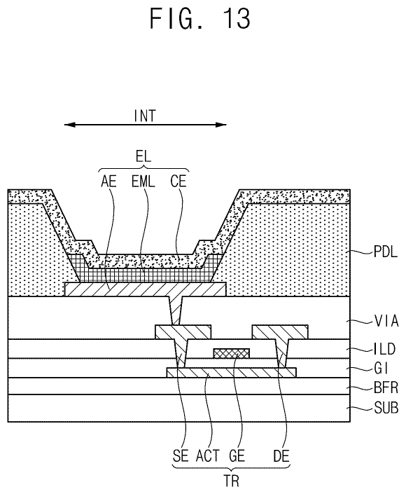

The <Table 1> summarizes the number of modes (labeled in left column) in which a pixel-per-accuracy (“PPA”) of a deposition using the mask stage MS may be compensated according to the number of the active blocks (labeled in top row). For example, a deformation of the mask MA may affect a deposition accuracy with which a pixel may be formed on a pre-set area (e.g., a pre-set area INT of FIG. 13). For example, the mode may include the distortion, the rotation, the U-shape, the XY reduction, the Y reduction, the Y expansion, the X reduction, and the X expansion in a case that the mask MA is transformed. In the table, the “O” means a case where the compensation is possible, and the “X” means a case where the compensation is not possible. The PPA may refer to a deposition accuracy with which a pixel is formed on a pre-set area (e.g., a pre-set area INT of FIG. 13).

In a case that there are eight active blocks, the rotation, the U-shape, and the XY reduction modes may be compensated.

On the other hand, in a case that the number of active blocks increases to 12, additional transformation modes (e.g., the Y reduction, the distortion, and the X reduction) of the mask MA may be compensated. For example, adjustments in the flatness of the mask stage MS may be made to achieve one or more transformation modes of the mask MA.

In the <Table 1>, the columns labeled as “12-A”, “12-B”, and “12-C” shown the modes in which the PPA compensation may be possible with 12 active blocks arranged to have different structures.

For example, in the case of the 12-A structure, the active blocks may be the 5th external height adjustment blocks OB5, OB5′, the 4th to 6th internal height adjustment blocks IB4, IB5, IB6, IB4′, IB5′, IB6′, the 11th internal height adjustment blocks IB11, IB11′, and the 16th internal height adjustment blocks IB16, IB16′. In this case, the rotation, the U-shape, the XY reduction, and the Y reduction modes of the mask MA may be compensated.

For example, in the case of the 12-B structure, the active blocks may be the 4th and 6th internal and external height adjustment blocks IB4, IB6, OB4, OB6, IB4′, IB6′, OB4′, OB6′, and the 12th and 15th internal height adjustment blocks IB12, IB15, IB12′, IB15′. In this case, the distortion, the rotation, the U-shape, the XY reduction, and the X reduction modes of the mask MA may be compensated.

In the case of the 12-C structure, as shown in FIG. 2, the active blocks may be the 4th internal height adjustment blocks IB4, IB4′, the 4th external height adjustment blocks OB4, OB4′, and the 6th internal height adjustment blocks IB4, IB4′, the 6th external height adjustment blocks OB6, OB6′, 11th external height adjustment blocks OB11, OB11′, and 16th external height adjustment block OB16, OB16′. In this case, the distortion, the rotation, the U-shape, the XY reduction, the Y reduction, and the X reduction modes of the mask MA may be compensated. By arranging the active blocks in the 12-C structure, a dispersion improvement effect of about 45% may be observed compared to the mask stage according to the comparative embodiment.

In a case that the number of active blocks increases to 16, the mask stage MS may additionally compensate to the Y expansion mode of the mask MA.

The mask stage MS and the deposition device 1 including the mask stage MS according to an embodiment of the disclosure may be configured to consider simplification and economic efficiency of the equipment structure and may include up to 12 of the active blocks to adjust for various mask MA deformation modes. In addition, the 12 active blocks may be arranged in the 12-C arrangement structure (e.g., refer to the alternating horizontal line patterns of FIG. 2) to adjust for various mask MA deformation modes.

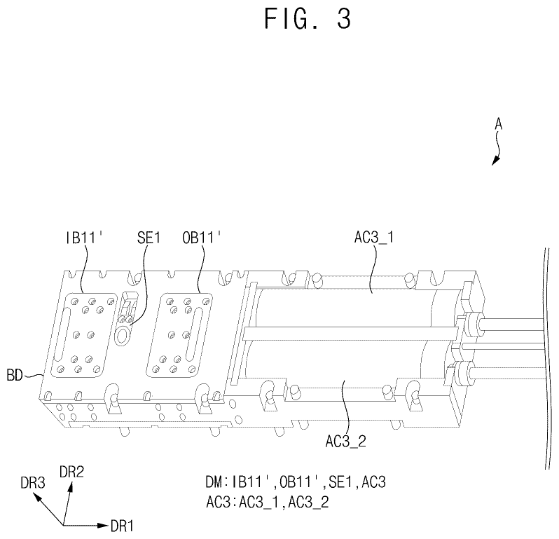

FIG. 3 is view illustrating an area A of FIG. 2.

Referring to FIG. 2 and FIG. 3, a driving module DM of the active block included in the mask stage MS may include the internal height adjustment block IB, the external height adjustment block OB, and at least one sensor. Other driving modules of the deposition device 1 may have a same or substantially similar structure. Therefore, hereinafter, descriptions will be focused on the area A, and overlapping descriptions may be omitted or simplified.

For example, the driving module DM may include the 11th internal height adjustment block IB11′, the 11th external height adjustment block OB11′, a first sensor SE1, and a third linear drive device AC3.

In an embodiment, the third linear drive device AC3 may include one or more actuators. For example, the third linear drive device AC3 may include a first actuator AC3_1 connected to the 11th external height adjustment block OB11′ and a second actuator AC3_2 connected to the 11th internal height adjustment block IB11′. The first actuator AC3_1 and the second actuator AC3_2 may be independently controlled. For example, a height of an upper surface of each of the 11th external height adjustment block OB11′ and the 11th internal height adjustment block IB11′ may be independently adjusted by the third linear drive device AC3.

In an embodiment, at least one first sensor SE1 may be disposed at each outer portion OU. For example, the first sensor SE1 may be disposed in each of the driving module DM. In this case, two first sensors SE1 may be disposed at each outer portion OU of the frame FR.

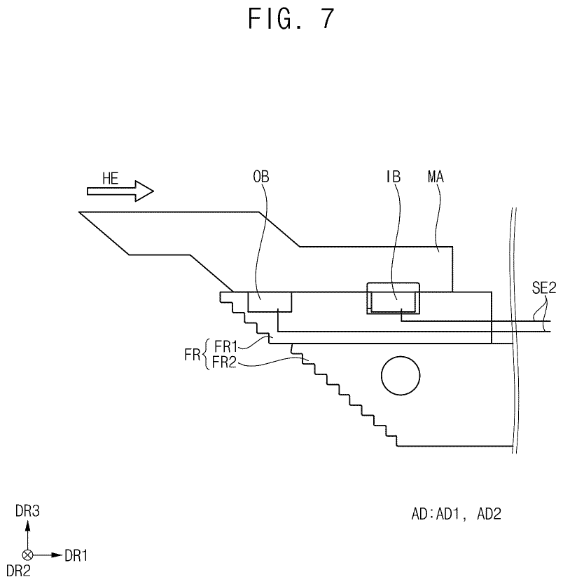

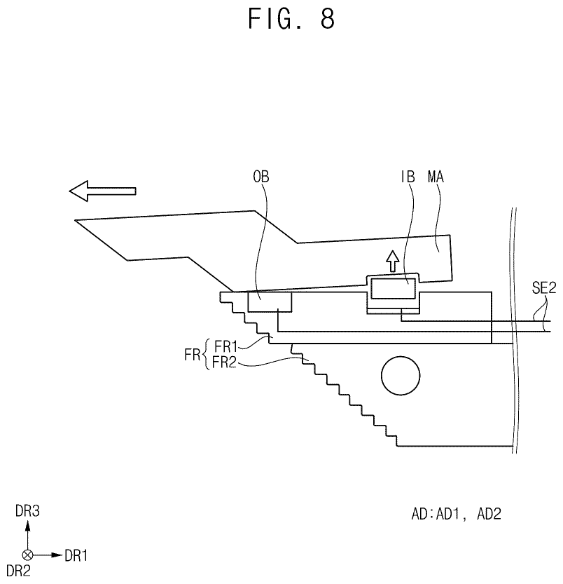

In an embodiment, the first sensor SE1 (e.g., the capacitive sensor) may be positioned between the height adjustment blocks to which the linear drive device AC is connected (e.g., the 11th internal height adjustment block IB11′ and the 11th external height adjustment block OB11′). However, the disclosure is not limited thereto. For example, to reduce cost of the driving module DM, although a first sensor SE1 has been described as being positioned between the internal and external height adjustment blocks (e.g., the 11th internal height adjustment block IB11′ and the 11th external height adjustment block OB11′), the first sensor SE1 may be arranged plurality. For another example, as described herein with reference to FIG. 7 and FIG. 8, the driving module may further include a second sensor that senses other information different from the first sensor.

FIG. 3 is illustrative, and the disclosure is not limited thereto. For example, the driving module DM may include other components, or some of the components may be omitted or changed.

For example, a body BD of the driving module DM may be at least partially disposed in the frame FR of the deposition device 1 of FIG. 1. However, the disclosure is not limited thereto. For example, the third linear driver AC3 may have a structure bent into an ‘L’ shape, which may be disposed to avoid an obstruction.

FIG. 4 is a cross-sectional view taken along a line I-I′ of FIG. 2.

Referring to FIG. 1, FIG. 2, and FIG. 4, for example, the frame FR of the mask stage MS may include a first frame portion FR1 and a second frame portion FR2.

For example, the second frame portion FR2 may support the first frame portion FR1. The first frame portion FR1 may be located on the second frame portion FR2. The first frame portion FR1 may have an upper surface US and a lower surface LS that are opposite each other in the third direction DR3. The upper surface US of the first frame portion FR1 may face the substrate SUB in the third direction DR3. The lower surface LS may face the deposition source DS in the third direction DR3.

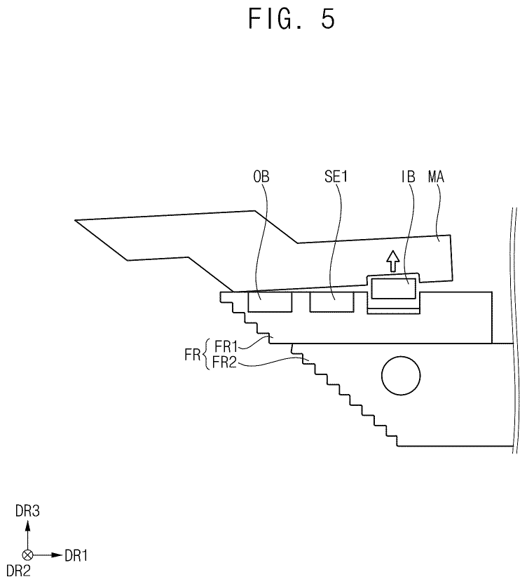

For example, a groove may be disposed in the upper surface US of the first frame portion FR1, and the driving module DM and the height adjustor (e.g., the height adjustor AD of FIG. 4 and FIG. 5) described herein may be disposed in the groove.

In an embodiment, a sensor (e.g., the first sensor SE1) may be disposed at each of the driving modules DM. The first sensor SE1 may be a capacitive sensor. The first sensor SE1 may detect a gap G between the mask MA seated on the frame FR and the height adjustment blocks (e.g., the internal height adjustment block IB and the external height adjustment block OB). The capacitive sensor may detect the gap G between the mask MA and the height adjustment blocks during an adjustment of the height adjustment blocks. However, the disclosure is not limited thereto. For example, the first sensor SE1 may be used without limitation as long as it is a sensor that may detect the gap G.

In an embodiment, the mask stage (e.g., the mask stage MS of FIG. 1) may further include the height adjustor AD disposed below each of the height adjustment blocks (e.g., the internal height adjustment block IB and the external height adjustment block OB). The height adjustor AD may have a pre-set height. The height adjustor AD may compensate for the flatness of the mask stage MS by the pre-set height. For example, the height adjustor AD may be a shim.

The height adjustor AD may be formed of a material including a metal, a metal alloy, or a ceramic. The height adjustor AD may have a plate shape. The height adjustor AD may have a pre-set height.

The height adjustor AD may include one or more height adjustors. For example, the height adjustor AD may include a first height adjustor AD1 and a second height adjustor AD2.

The first height adjustor AD1 may be disposed below the external height adjustment block OB and may have a first height.

The second height adjustor AD2 may be disposed below the internal height adjustment block IB and may have a second height. For example, the first height and the second height may be the same height or different heights. For example, a flatness of the mask MA may be adjusted by adding or removing one or more height adjustors AD

FIG. 5 is a view illustrating the height adjustment block included in the mask stage of FIG. 2.

Referring to FIG. 2, FIG. 4, and FIG. 5, the height of the internal height adjustment blocks IB and/or the external height adjustment blocks OB may be changed by the linear driver AC. Accordingly, the flatness of the mask MA disposed on the height adjustment block(s) (e.g., internal height adjustment blocks IB and/or external height adjustment blocks OB) may be adjusted. For example, a flatness of the mask MA may be adjusted by adjusting the internal height adjustment blocks IB and/or the external height adjustment blocks OB of the mask stage MS.

For example, in a case that the internal height adjustment blocks IB are raised by the linear driver AC, an edge portion of the mask MA may be raised in the third direction DR3. According to an embodiment, an adjustment of the internal height adjustment blocks IB may apply a force to the mask MA.

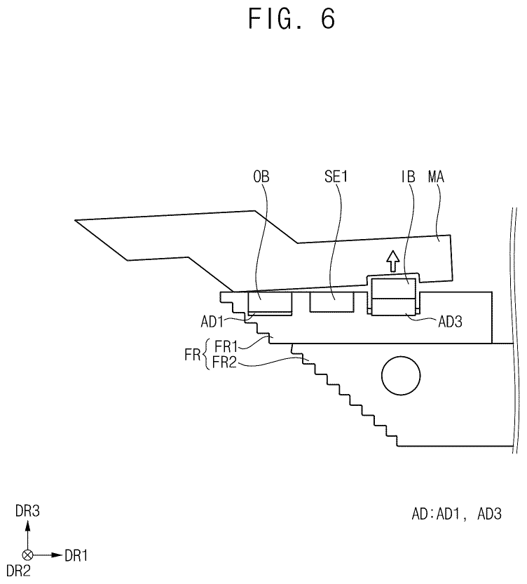

FIG. 6 is a view illustrating the height adjustor included in the mask stage of FIG. 2.

Referring to FIG. 2, FIG. 4, and FIG. 6, the height adjustor AD may have a pre-set height.

According to an embodiment, the mask MA may be an inspection mask disposed on the mask stage MS. The inspection mask may be a mask that includes a sensor capable of acquiring displacement data.

Based on the displacement data obtained from the inspection mask, the height adjustor AD may be disposed in the frame FR. For example, the height adjustor AD with a certain height may be disposed in a location, e.g., at one or more of the height adjustment blocks BL, to improve a flatness of the mask stage MS.

For example, the deposition device 1 may include one or more of the height adjustors AD. For example, the height adjustors AD may be placed at one or more locations on the frame FR, and the flatness of the mask stage MS may be precisely adjusted.

For example, the third height adjustor AD3 may have a greater height in the third direction DR3 than the second height adjustor AD2. Accordingly, the edge portion of the mask MA may be raised above the upper surface of the first frame portion FR1 in the third direction DR3. For example, the edge portion of the mask MA, disposed away from the opening portion OP of the frame FR, may be raised relatively higher above the upper surface of the first frame portion FR1 than an inside portion of the mask MA proximate to the opening portion OP. However, the disclosure is not limited thereto.

The height adjustor AD of FIG. 5 and FIG. 6 may be disposed below the height adjustment block(s) (e.g., internal height adjustment blocks IB and/or external height adjustment blocks OB).

A deposition process may be carried out at relatively high temperature and pressure. The mask MA may be deformed by the temperature and/or pressure. In this case, compensation of the PPA of the mask MA and the mask stage MS may be compensated.

As described herein, the height adjustor AD may be difficult to replace in a process chamber, for example, while in the vacuum state. However, the active block according to an embodiment of the disclosure may be connected to a linear driver AC, and the linear driver AC may be adjusted in the process chamber, and in a vacuum state, and the compensation of the PPA of the mask MA and the mask stage MS may be possible in the process chamber.

FIG. 7 and FIG. 8 are views illustrating a second sensor included in the mask stage of FIG. 2.

Referring to FIG. 2, FIG. 7, and FIG. 8, the mask MA may be deformed in a heat-deformation direction HE due to an increase in temperature. For example, the mask MA may deform in the heat-deformation direction HE. In this case, a pixel formed using the mask MA may be formed on unintended area of the substrate SUB.

To form the pixel in an intended area, the compensation of the PPA of the mask MA and the mask stage MS may be performed. For example, as described herein, the internal height adjustment blocks IB may rise and the mask MA may be moved in a direction opposite to the heat-deformation direction HE. Accordingly, the PPA of the mask MA and the mask stage MS may be compensated.

To this end, in an embodiment, the deposition device (e.g., the deposition device 1 of FIG. 1) may further include a second sensor SE2.

In an embodiment, the second sensor SE2 may be a temperature sensor (i.e., thermal couple) disposed in the outer portion OU of the frame FR and may detect the temperature of the mask MA.

In an embodiment, the temperature sensor may detect the temperature of the mask MA. Based on the temperature of the mask MA, a compensation amount for the PPA of the mask MA and the mask stage MS may be calculated. The compensation amount may be used to compensate for a thermal-deformation of the mask MA.

FIG. 9, FIG. 10, FIG. 11, and FIG. 12 are views illustrating a height adjustment block included in the mask stage MS of FIG. 2.

Referring to FIGS. 9 to 12, in an embodiment, a height adjustment block BL connected to the linear driving device AC may have a wedge structure. For example, the height adjustment block BL may include a first wedge WE1, a second wedge WE2, and a moving axis RO.

In an embodiment, the first wedge WE1 may include a first inclined surface IS1.

In an embodiment, the second wedge WE2 may include a second inclined surface IS2. The second inclined surface IS2 may contact the first inclined surface IS1. The second wedge WE2 may be disposed on the first wedge WE in the third direction DR3. The second wedge WE2 may may completely or partially overlap the first wedge WE1 in the third direction DR3.

In an embodiment, a moving axis RO may be parallel to a bottom surface BS of the second wedge WE2. The moving axis RO may move linearly in the first direction DR1 or in the direction opposite to the first direction DR1 relative to a base portion BP. For example, the base portion BP may be the body BD of the driving module DM. The moving axis RO may be connected to the linear driver AC, and the linear driver AC may impart a force to move the moving axis RO.

For example, the moving axis RO may include a cross roller rail. The cross roller rail may be a device that moves along a linear pathway when a force is applied by the linear driver AC. For example, the cross roller may have low friction. However, the disclosure is not limited thereto.

In an embodiment, as shown in FIG. 9, FIG. 11, and FIG. 12, in a case that the second wedge WE2 moves in the direction opposite to the first direction DR1, the first wedge WE1 may move in the third direction DR3. For example, a height of the height adjustment block BL may be increased. In some embodiments, as shown in FIGS. 10 to 12, in a case that the second wedge WE2 moves in the first direction DR1, the first wedge WE1 may move in the direction opposite to the third direction DR3. For example, a height of the height adjustment block BL may be decreased.

For example, a slope of the first inclined surface IS1 and the second inclined surface IS2 may be about 1: N (wherein the N is a natural number of about 2 or more). For example, the N may be about 15. In this case, in a case that the linear driver AC moves the moving axis RO by about 1 millimeter (mm), the first wedge WE1 may rise by about 1/15 mm in the third direction DR3. In other words, with a change in a height of the height adjustment block BL in the third direction DR3 being about 1/15 times the movement of moving axis RO, a power of the linear drive AC may be amplified by about 15 times.

According to an embodiment, the linear driver AC may apply a force to the height adjustment blocks BL. The force may be translated by the height adjustment blocks BL to adjust the gap G between the upper surface US of the first frame portion FR1. According to an embodiment, a change in the gap G may result in a transformation of the mask MA.

According to an embodiment, the linear driver AC may be controlled by a controller to move by different compensation amounts in different sections. For example, in a first section in which a range where the gap G is between about 0 micrometers to about 50 micrometers, a tilt compensation may be compensated in large increments, and in a second section in which the gap G is between about 50 micrometers to about 250 micrometers, the tilt compensation may be compensated in small increments. In other words, the compensation amount may change based on a current gap G. For example, the compensation amount may be large when the gap G is small and may be small with the G is large. For example, when the gap G is large, e.g., greater than about 50 micrometers, the compensation amount may be adjusted in small increments to compensate more precisely. The linear driver AC may be controlled to move in different compensation amounts in two or more sections. However, the disclosure is not limited thereto, and the linear driver AC may apply a same compensation amount throughout a range of the gap G, e.g., in one section.

The wedge structure may support high loads by including a high rigidity and high precision cross roller.

As described herein, the mask stage MS according to embodiments of the disclosure may secure a compensation amount for a mask MA disposed in a process chamber and may be used for manufacturing and verification of the mask MA.

For example, deposition equipment may be provided for a deposition process, and a production target may be secured through a process in which a target mask may be use as a mass production mask. For example, the target mask may be disposed in the deposition equipment, a deposition process may be performed for a test substrate, and a deposition may be evaluated. A flatness of the mask stage MS may be adjusted based on the evaluation. For example, the evaluation may be a PPA evaluation.

The deposition process may be performed once again using the target mask and the mask stage MS (flattened), and the PPA may be evaluated, which may verify a consistency of the flatness adjustment. For example, if the PPA value is within an intended range, a mass production set of devices may be manufactured on the substrate(s) SUB. For another example, if the PPA value is outside the intended range, the flatness of the mask stage MS may be adjusted once again.

As described herein, the deposition process may be performed under the high temperature and high pressure, which may affect the flatness of the mask stage MS, and a compensation may be performed prior to performing a deposition process of the mass production set of devices. In an embodiment, the flatness of the mask stage MS may be adjusted again during equipment operation.

For example, the mask MA on which the deposition process is performed may be deformed by the high temperature and high pressure during equipment operation. In this case, the compensation of the deformation of the mask MA may be performed. In an embodiment, the height adjustment blocks BL may be disposed in a frame FR or the mask stage MS on which the mask MA is seated. Accordingly, the flatness of the mask stage MS and the mask MA may be adjusted in an environment of the chamber CH in which the deposition process is performed.

FIG. 13 is a view illustrating a pixel formed by the deposition process using the deposition device of FIG. 1.

Referring to FIG. 13, the pixel may include a base substrate BS, a buffer layer BFR, a transistor TR, a gate insulating layer GI, an interlayer insulating layer ILD, a via insulating layer VIA, a light-emitting diode EL, and a pixel defining layer PDL in the pre-set area INT.

The transistor TR may include an active layer ACT, a gate electrode GE, a source electrode SE, and a drain electrode DE. The light-emitting diode EL may include a first electrode AE, an emission layer EML, and a second electrode CE.

The base substrate BS may include glass, quartz, or plastic. For example, the base substrate BS may have flexible, bendable, or rollable characteristics.

The buffer layer BFR may be disposed on the base substrate BS. The buffer layer BFR may include an inorganic insulating material. For example, the buffer layer BFR may include silicon oxide, silicon nitride, or silicon oxynitride. The buffer layer BFR may block impurities so that the active layer ACT of the transistor TR may not be damaged by the impurities diffused through the base substrate BS.

The active layer ACT may be disposed on the buffer layer BFR. For example, the active layer ACT may include a silicon semiconductor. For example, the active layer ACT may include amorphous silicon or polycrystalline silicon. For another example, the active layer ACT may include an oxide semiconductor. For example, the active layer ACT may include zinc oxide, zinc-tin oxide, zinc-indium oxide, indium oxide, titanium oxide, indium-gallium-zinc oxide, or indium-zinc-tin oxide.

The gate insulating layer GI may be disposed on the active layer ACT. The gate insulating layer GI may include an inorganic insulating material. For example, the gate insulating layer GI may include silicon oxide, silicon nitride, silicon oxynitride, titanium oxide, or tantalum oxide. The gate insulating layer GI may electrically insulate the active layer ACT and the gate electrode GE from each other.

The gate electrode GE may be disposed on the gate insulating layer GI. The gate electrode GE may include a conductive material. For example, the gate electrode GE may include a metal, an alloy, a conductive metal oxide, or a transparent conductive material. A gate signal may be applied to the gate electrode GE. The gate signal may turn on/off the transistor TR to adjust electrical conductivity of the active layer ACT.

The interlayer insulating layer ILD may be disposed on the gate electrode GE. The interlayer insulating layer ILD may include an organic insulating material and/or an inorganic insulating material. The interlayer insulating layer ILD may electrically insulate the source electrode SE and drain electrode DE from the gate electrode GE.

The source electrode SE and the drain electrode DE may be disposed on the interlayer insulating layer ILD. Each of the source electrode SE and the drain electrode DE may include a conductive material. For example, each of the source electrode SE and the drain electrode DE may include a metal, an alloy, a conductive metal oxide, or a transparent conductive material. Each of the source electrode SE and the drain electrode DE may electrically contact the active layer ACT through a contact hole (or contact opening) passing through the interlayer insulating layer ILD and the gate insulating layer GI.

The via insulating layer VIA may be disposed on the source electrode SE and the drain electrode DE. The via insulating layer VIA may include an organic insulating material. For example, the via insulating layer VIA may include a polyacrylic resin, a polyimide resin, or an acrylic resin. Accordingly, an upper surface of the via insulating layer VIA may be substantially flat.

The first electrode AE may be disposed on the via insulating layer VIA. The first electrode AE may include a conductive material. For example, the first electrode AE may include a metal, an alloy, a conductive metal oxide, or a transparent conductive material. The first electrode AE may electrically contact the source electrode SE or the drain electrode DE through a contact hole (or contact opening) penetrating the via insulating layer VIA.

The pixel defining layer PDL may be disposed on the first electrode AE. The pixel defining layer PDL may include an organic insulating material. For example, the pixel defining layer PDL may include a polyacryl-based compound or a polyimide-based compound. The pixel defining layer PDL may partition the emission region of each of the pixels PX. The pixel defining layer PDL may include a pixel opening exposing the first electrode AE.

The emission layer EML may be disposed on the first electrode AE in the pixel opening. The emission layer EML may include an organic emission material. In an embodiment, the emission layer EML may have a multi-layer structure including various functional layers. For example, the emission layer EML may include at least one of a hole injection layer, a hole transport layer, an electron transport layer, or an electron injection layer.

The second electrode CE may be disposed on the emission layer EML and may cover the pixel defining layer PDL.

For example, the emission layer EML may be formed by depositing a deposition material on the first electrode AE. The emission layer EML may be formed by a deposition method using the deposition device (e.g., the deposition device of FIG. 1).

However, the disclosure is not limited thereto, and a layer formed through the deposition process may be a functional layer, such as the hole transport layer or the electron transport layer. For another example, the layer formed through the deposition process may be a capping layer or an encapsulation layer disposed on the second electrode CE.

As described herein, an evaluation of a deposited layer, e.g., in a PPA evaluation, may be enhanced by forming the layer using the deposition device 1 of FIG. 1 including the mask stage MS of FIG. 2. In an embodiment, a yield of the display device including the pixel on which the deposition process is completed in the deposition device 1 may be improved.

The mask stage and the deposition device 1 including the mask stage MS according to embodiments may be applied to a manufacturing process of various display devices included in a computer, a notebook, a cell phone, a smart phone, a smart phone, a PMP, a PDA, or a MP3 player.

The above description is an example of technical features of the disclosure, and those skilled in the art to which the disclosure pertains will be able to make various modifications and variations. Thus, embodiments of the disclosure described herein may be implemented separately or in combination with each other. Embodiments disclosed in the disclosure are examples, and are not limiting on the technical spirit of the disclosure. Embodiments describe the technical spirit of the disclosure, and do not limit the scope of the technical spirit of the disclosure. Therefore, it is to be understood that the foregoing is illustrative of various embodiments and is not to be construed as limiting, and that modifications to embodiments, as well as other embodiments, are intended to be included within the scope of the appended claims.

What is claimed is:

1. A mask stage comprising:
a frame including an opening portion and an outer portion surrounding the opening portion, the outer portion including a first outer portion, a second outer portion, a third outer portion, and a fourth outer portion, disposed in a plane defined by a first direction and a second direction crossing the first direction;
a plurality of internal height adjustment blocks disposed at the first outer portion, the second outer portion, the third outer portion, and the fourth outer portion;
a plurality of external height adjustment blocks disposed at the first outer portion, the second outer portion, the third outer portion, and the fourth outer portion and disposed spaced apart from the opening portion with the plurality of internal height adjustment blocks disposed therebetween; and
a plurality of linear drivers connected to the plurality of internal height adjustment blocks and the plurality of external height adjustment blocks.

2. The mask stage of claim 1, wherein,
the first outer portion and the third outer portion are first sides parallel to each other in the first direction,
the second outer portion and the fourth outer portion are second sides parallel to each other in the second direction,
two or more of the plurality of external height adjustment blocks are disposed at each of the second sides and at each of the first sides, and
two or more of the plurality of internal height adjustment blocks are disposed at each of the second sides and at each of the first sides.

3. The mask stage of claim 1, wherein each linear driver of the plurality of linear drivers is connected to an internal height adjustment block of the plurality of internal height adjustment blocks and an external height adjustment block of the plurality of external height adjustment blocks.

4. The mask stage of claim 1, wherein first linear drivers of the plurality of linear drivers are disposed adjacent to a center portion of each of the first and third outer portions and second linear drivers of the plurality of linear drivers are disposed adjacent to opposite end portions of each of the second and fourth outer portions.

5. The mask stage of claim 1, further comprising a plurality of passive height adjustment blocks disposed at each of the first to fourth outer portions,
wherein the plurality of internal height adjustment blocks and the plurality of external height adjustment blocks are active height adjustment blocks connected to the plurality of linear drivers.

6. The mask stage of claim 1, further comprising:
a temperature sensor disposed at the outer portion that detects a temperature of a mask disposed on the frame.

7. The mask stage of claim 6, wherein the temperature sensor is disposed adjacent to the internal height adjustment block and the external height adjustment block connected to a first linear driver of the plurality of linear drivers.

8. The mask stage of claim 1, further comprising a first sensor configured to detect a gap between a mask disposed on the frame and the frame.

9. The mask stage of claim 8, wherein the first sensor is positioned between the internal height adjustment block and the external height adjustment block connected to a first linear driver of the plurality of linear drivers.

10. The mask stage of claim 1,
wherein each height adjustment block of the plurality of internal height adjustment blocks and the plurality of external height adjustment blocks connected to a linear driver of the plurality of linear drivers includes:
a first wedge including a first incline surface;
a second wedge including a second incline surface contacting the first incline surface and disposed in a third direction crossing both the first direction and the second direction; and
a moving axis connected to the second wedge and moveable, by the linear driver, in the first direction,
wherein a movement of the second wedge in the first direction moves the first wedge in the third direction.

11. The mask stage of claim 1, further comprising:
a height adjustor disposed below at least one height adjustment block of the plurality of internal height adjustment blocks or the plurality of external height adjustment blocks, and having a pre-set height.

12. A mask stage comprising:
a frame including an opening portion and an outer portion surrounding the opening portion, the outer portion including a first outer portion, a second outer portion, a third outer portion, and a fourth outer portion, disposed in a plane defined by a first direction and a second direction crossing the first direction;
a plurality of internal height adjustment blocks disposed at the first outer portion, the second outer portion, the third outer portion, and the fourth outer portion;
a plurality of external height adjustment blocks disposed at the first outer portion, the second outer portion, the third outer portion, and the fourth outer portion and disposed spaced apart from the opening portion with the plurality of internal height adjustment blocks disposed therebetween; and
a plurality of linear drivers, wherein each linear driver of the plurality of linear drivers includes a first actuator connected to an internal height adjustment block of the plurality of internal height adjustment blocks and a second actuator connected to an external height adjustment block of the plurality of external height adjustment blocks.

13. The mask stage of claim 12, further comprising a sensor configured to sense a gap between a mask disposed on the frame and the frame, and positioned between the internal height adjustment block and the external height adjustment block of each linear driver of the plurality of linear drivers.

14. A deposition device comprising:
a deposition source disposed in a chamber;
a mask disposed opposite to the deposition source;
and a mask stage that supports the mask including:
a frame including an opening portion and an outer portion surrounding the opening portion, the outer portion including a first outer portion, a second outer portion, a third outer portion, and a fourth outer portion, disposed in a plane defined by a first direction and a second direction crossing the first direction;
a plurality of internal height adjustment blocks disposed at the first outer portion, the second outer portion, the third outer portion, and the fourth outer portion;
a plurality of external height adjustment blocks disposed at the first outer portion, the second outer portion, the third outer portion, and the fourth outer portion and disposed spaced apart from the opening portion with the plurality of internal height adjustment blocks disposed therebetween; and
a plurality of linear drivers connected to the plurality of internal height adjustment blocks and the plurality of external height adjustment blocks.

15. The deposition device of claim 14, wherein the plurality of linear drivers are operable in a vacuum state within the chamber.

16. The deposition device of claim 14, wherein,
the first outer portion and the third outer portion are first sides parallel to each other in the first direction,
the second outer portion and the fourth outer portion are second sides parallel to each other in the second direction,
two or more of the plurality of external height adjustment blocks are disposed at each of the second sides and at each of the first sides, and
two or more of the plurality of internal height adjustment blocks are disposed at each of the second sides and at each of the first sides.

17. The deposition device of claim 14, further comprising a plurality of passive height adjustment blocks disposed at each of the first to fourth outer portions,
wherein the plurality of internal height adjustment blocks and the plurality of external height adjustment blocks are active height adjustment blocks connected to the plurality of linear drivers.

18. The deposition device of claim 14, further comprising:
a temperature sensor disposed at the outer portion that detects a temperature of the mask disposed on the frame.

19. The deposition device of claim 14, further comprising a first sensor disposed on the frame and configured to detect a gap between the mask and the frame.

20. The deposition device of claim 14,
wherein each height adjustment block of the plurality of internal height adjustment blocks and the plurality of external height adjustment blocks connected to a linear driver of the plurality of linear drivers includes:
a first wedge including a first incline surface;
a second wedge including a second incline surface contacting the first incline surface and disposed in a third direction crossing both the first direction and the second direction; and
a moving axis connected to the second wedge and moveable, by the linear driver, in the first direction,
wherein a movement of the second wedge in the first direction moves the first wedge in the third direction.
